(19) United States
(12) Patent Application Publication
(10) Pub. No.: US 2024/0072736 A1
(43) Pub. Date: Feb. 29, 2024

(54) AMPLIFIER DC BIAS PROTECTION CIRCUIT AND RELATED AUDIO SYSTEM

(71) Applicant: ACER INCORPORATED, New Taipei City (TW)

(72) Inventors: Po-Jen Tu, New Taipei City (TW); Jia-Ren Chang, New Taipei City (TW); Kai-Meng Tzeng, New Taipei City (TW); Ming-Chun Yu, New Taipei City (TW)

(73) Assignee: ACER INCORPORATED, New Taipei City (TW)

(21) Appl. No.: 18/073,506

(22) Filed: Dec. 1, 2022

(30) Foreign Application Priority Data
Aug. 24, 2022 (TW) 111131941

(51) Int. Cl. H03F 1/52; H03F 3/68

(52) U.S. Cl. CPC H03F 1/52; H03F 3/68; H03F 2200/03

(57) ABSTRACT

An amplifier DC bias protection circuit includes an amplifier module, a filter module and a comparator module. The amplifier module converts an input signal into a non-inverting signal and an inverting signal. The filter module blocks AC signals in the non-inverting signal and the inverting signal, thereby providing a first DC bias signal and a second DC bias signal accordingly. The comparator module is configured to determine whether the absolute value of a DC bias difference signal is greater than a predetermined value, and output a determination signal for deactivating the amplifier module when the absolute value of the DC bias difference signal is greater than the predetermined value. The DC bias difference signal is associated with the voltage difference between the first DC bias signal and the second DC bias signal.

### BACKGROUND OF THE INVENTION

### 1. Field of the Invention

The present invention is related to an amplifier DC bias protection circuit and related audio system, and more particularly, to an amplifier DC bias protection circuit and related audio system capable of providing signal amplification and DC bias protection.

### 2. Description of the Prior Art

Amplifiers are used in consumer audio system for amplifying the waveform sent to it by a preamplifier without introducing much distortion. Each amplifier class comes with its own set of strengths and weaknesses. A Class-A amplifier is conducting through all the period of the signal and characterized in larger quiescent current and smaller distortion, but is disadvantageous in having low power efficiency and high heat sink requirement. A Class-B amplifier is conducting only for one-half the input period and characterized in smaller quiescent current and higher power efficiency, but is disadvantageous in having larger distortion. In a Class-AB amplifier, the conduction angle is intermediate between a Class-A amplifier and a Class-B amplifier. Class-AB amplifiers are widely considered a good compromise for amplifiers with intermediate quiescent current, intermediate distortion, and intermediate power efficiency.

Class-D amplifiers have become increasingly popular in recent year. A Class-D amplifier operates its output device in a switching manner, thereby achieving high power efficiency. Compared to an equivalent Class-AB device, a class-D amplifier's lower losses does not require the use of a heat sink or cooling device while also reducing the amount of input power required, allowing for a lower-capacity power supply design. Therefore, Class-D amplifiers are typically smaller than an equivalent Class-AB amplifier, and thus more suitable for use in portable electronic devices.

In a Class-D amplifier, an analog signal is converted into a stream of pulse-width modulation (PWM) signals for driving active devices (transistors). Each switch is either completely on or completely off for functioning as an electronic switch instead of a linear gain device, thereby lowering the power loss at the output stage and achieving high-efficient signal amplification. A Class-D amplifier is configured amplify an input signal with zero direct-current (DC) bias and generate a non-inverting signal and an inverting signal for driving a speaker, wherein the non-inverting signal and the inverting signal have the DC biases equal to the same absolute value. Therefore, the DC biases of the non-inverting signal and the inverting signal may be completely canceled at the speaker for providing a speaker output signal with zero DC bias.

However, since the characteristics of electronic devices are easily influenced due to process variations, the P-type transistors and the N-type transistors in the Class-D amplifier may have different DC biases due to DC offset. Under such circumstance, the non-inverting signal and the inverting signal generated by the Class-D amplifier have DC biases with different absolute values, resulting in the speaker output signal with non-zero DC bias. If the non-inverting signal and the inverting signal have DC biases with different absolute values when the Class-D amplifier is turned on, the resulting speaker output signal with non-zero DC bias may produce pop noise and even damage the circuit.

Therefore, there is a need for an amplifier DC bias protection circuit capable of providing signal amplification and DC bias protection in audio equipment.

### SUMMARY OF THE INVENTION

The present invention provides an amplifier DC bias protection circuit which includes an amplifier module, a filter module and a comparator module. The amplifier module is configured to convert an input signal into a non-inverting signal and an inverting signal. The filter module is configured to block an AC component in the non-inverting signal for providing a corresponding first DC bias signal and block an AC component in the inverting signal for providing a corresponding second DC bias signal. The comparator module is configured to determine whether an absolute value of a DC bias difference signal is greater than a predetermined value and output a determination signal for deactivating the amplifier module when the absolute value of the DC bias difference signal is greater than the predetermined value. The DC bias difference signal is associated with a voltage difference between the first DC bias signal and the second DC bias signal.

The present invention also provides an audio system which provides signal amplification and DC bias protection. The audio system includes a speaker module and an amplifier DC bias protection circuit. The amplifier DC bias protection circuit includes an amplifier module, a filter module and a comparator module. The amplifier module is configured to convert an input signal into a non-inverting signal and an inverting signal for driving the speaker module. The filter module is configured to block an AC component in the non-inverting signal for providing a corresponding first DC bias signal and block an AC component in the inverting signal for providing a corresponding second DC bias signal. The comparator module is configured to determine whether an absolute value of a DC bias difference signal is greater than a predetermined value and output a determination signal for deactivating the amplifier module when the absolute value of the DC bias difference signal is greater than the predetermined value. The DC bias difference signal is associated with a voltage difference between the first DC bias signal and the second DC bias signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional diagram illustrating an audio system which provides signal amplification and DC bias protection according to an embodiment of the present invention.

FIG. 2 is a diagram illustrating an implementation of an amplifier module in an amplifier DC bias protection circuit according to an embodiment of the present invention.

FIG. 3 is a diagram illustrating an implementation of a filter module in an amplifier DC bias protection circuit according to an embodiment of the present invention.

FIG. 4 is a diagram illustrating an implementation of a comparator module in an amplifier DC bias protection circuit according to an embodiment of the present invention.

FIG. 5 is a diagram illustrating related signals during the operation of an amplifier DC bias protection circuit in an ideal condition according to an embodiment of the present invention.

FIG. 6 is a diagram illustrating related signals during the operation of an amplifier DC bias protection circuit in a non-ideal condition according to an embodiment of the present invention.

### DETAILED DESCRIPTION

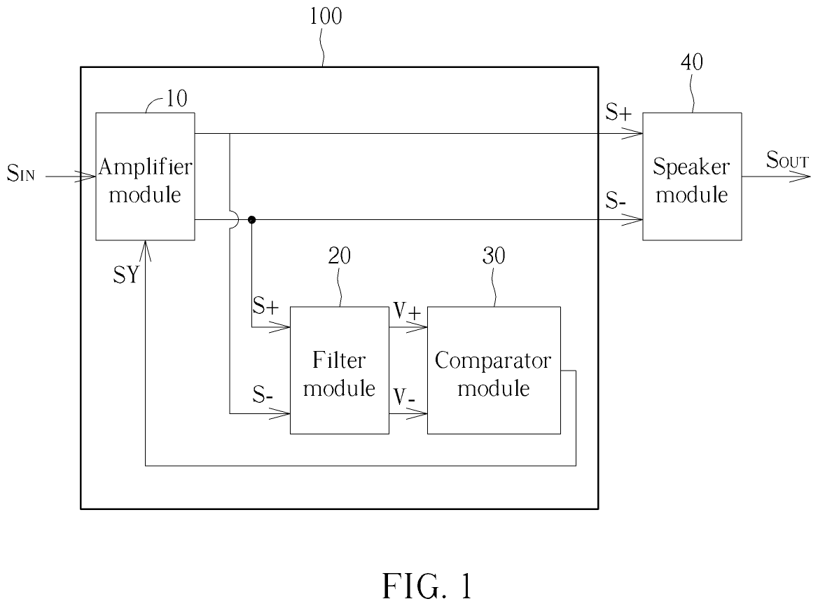

FIG. 1 is a functional diagram illustrating an audio system which provides signal amplification and DC bias protection according to an embodiment of the present invention. The audio system includes an amplifier DC bias protection circuit 100 and a speaker module 40. The amplifier DC bias protection circuit 100 includes an amplifier module 10, a filter module 20 and a comparator module 30. The amplifier module 10 is configured to convert an input signal S_{IN} into a non-inverting signal S+ and an inverting signal S− for driving the speaker module 40. The filter module 20 is coupled between the amplifier module 10 and the comparator module 30 for blocking alternative-current (AC) components in the non-inverting signal S+ and the inverting signal S−, thereby providing corresponding DC bias signals V+ and V−. The comparator module 30 is configured to determine whether the voltage difference between the DC bias signal V+ and the DC bias signal V− is greater than a predetermined value, and output a determination signal SY accordingly. During operation, the amplifier module 10 may be deactivated by the determination signal SY having a specific level. In an embodiment, the amplifier DC bias protection circuit 100 may be applied in a Class-D amplifier, but not limited thereto.

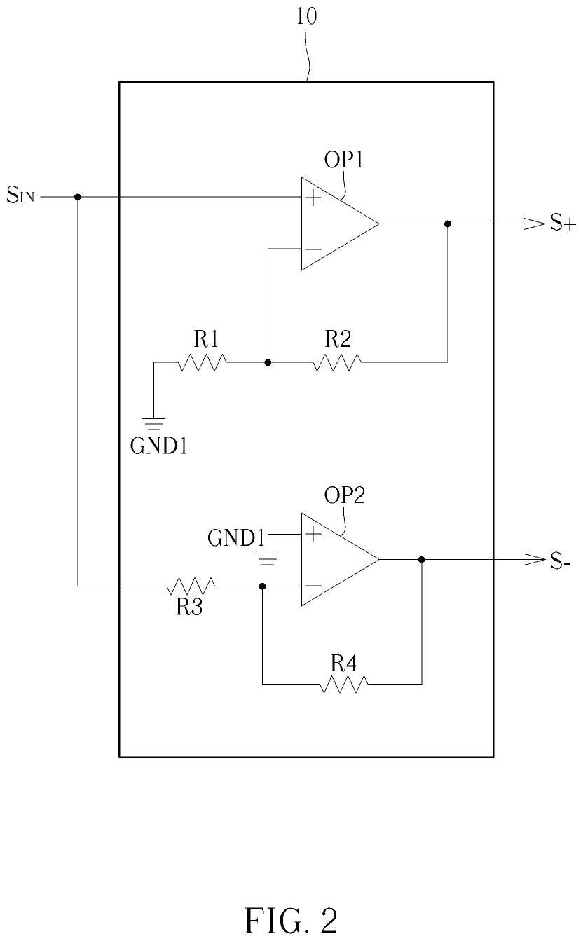

FIG. 2 is a diagram illustrating an implementation of the amplifier module 10 in the amplifier DC bias protection circuit 100 according to an embodiment of the present invention. The amplifier module 10 may include operational amplifiers OP1-0P2 and resistors R1-R4. The operational amplifier OP1 includes a non-inverting input end coupled to the input signal S_{IN}, an inverting input end coupled to a ground voltage GND1 via the resistor R1, and an output end coupled to the inverting input end of the operational amplifier OP1 via the resistor R2 for outputting the non-inverting signal S+. The operational amplifier OP2 includes a non-inverting input end coupled to the ground voltage GND1, an inverting input end coupled to the input signal S_{IN} via the resistor R3, and an output end coupled to the inverting input end of the operational amplifier OP2 via the resistor R4 for outputting the inverting signal S−.

During the operation of the operational amplifier OP1, the resistors R1 and R2 provide a negative feedback path which creates a virtual ground (the voltage difference between the non-inverting input end and the inverting input end of the operational amplifier OP1 is essentially zero). Under such circumstance, the relation between the non-inverting signal S+ and the input signal S_{IN} may be represented by S+=(1+R2/R1)*S_{IN}, which means the gain G1 of the operational amplifier OP1 is equal to (1+R2/R1). During the operation of the operational amplifier OP2, the resistors R3 and R4 provide a negative feedback path which creates a virtual ground (the voltage difference between the non-inverting input end and the inverting input end of the operational amplifier OP2 is essentially zero). Under such circumstance, the relation between the inverting signal S− and the input signal S_{IN} may be represented by S−=−(R4/R3)*S_{IN}, which means the gain G2 of the operational amplifier OP2 is equal to −(R4/R3). In an embodiment of the present invention, the values of the resistors R1-R4 are determined in a way so that G1=−G2, which allows the non-inverting signal S+ and the inverting signal S− to have the same DC bias and opposite phases. It is to be noted that the circuit structure depicted in FIG. 2 is merely an embodiment of the present amplifier module 10, but does not limit the scope of the present invention.

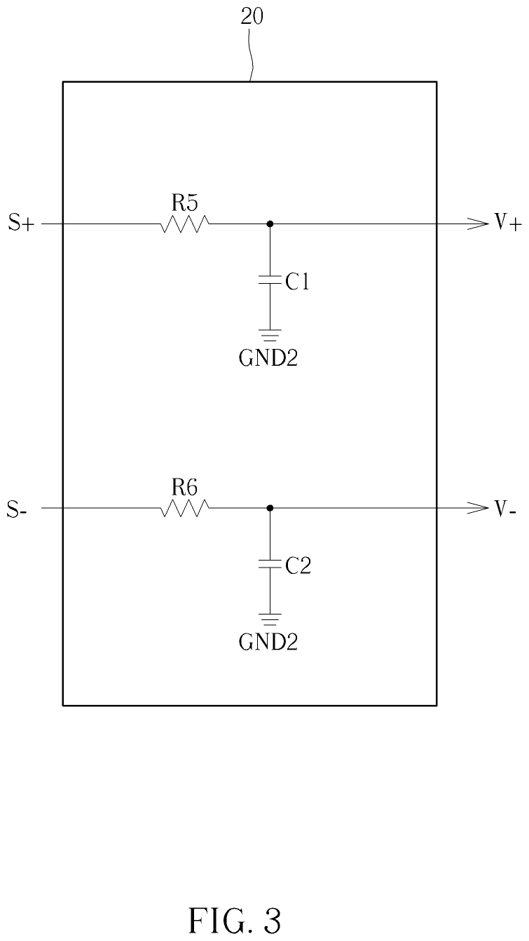

FIG. 3 is a diagram illustrating an implementation of the filter module 20 in the amplifier DC bias protection circuit 100 according to an embodiment of the present invention. The filter module 20 includes resistors R5-R6 and capacitors C1-C2. The first end of the resistor R5 is coupled to the amplifier module 10 for receiving the non-inverting signal S+, and the second end of the resistor R5 is for outputting a DC bias signal V+to the comparator module 30. The first end of the resistor R6 is coupled to the amplifier module 10 for receiving the inverting signal S−, and the second end of the resistor R6 is for outputting a DC bias signal V− to the comparator module 30. The capacitor C1 is coupled between the second end of the resistor R5 and a ground voltage GND2, and the capacitor C2 is coupled between the second end of the resistor R6 and the ground voltage GND2. The resistor R5 and the capacitor C1 form a low-pass filter configured to provide the DC bias signal V+ by blocking the AC component in the non-inverting signal S+, wherein the DC bias signal V+ is associated with the DC bias voltage of the non-inverting signal S+. The resistor R6 and the capacitor C2 forma low-pass filter configured to provide the DC bias signal V− by blocking the AC component in the inverting signal S−, wherein the DC bias signal V− is associated with the DC bias voltage of the non-inverting signal S−. In an embodiment of the present invention, the values of the resistors R5-R6 and the capacitors C1-C2 are determined in a way so that the filter module 20 may provide the same cut-off frequency to the non-inverting signal S+ and the inverting signal S−. It is to be noted that the circuit structure depicted in FIG. 3 is merely an embodiment of the present filter module 20, but does not limit the scope of the present invention.

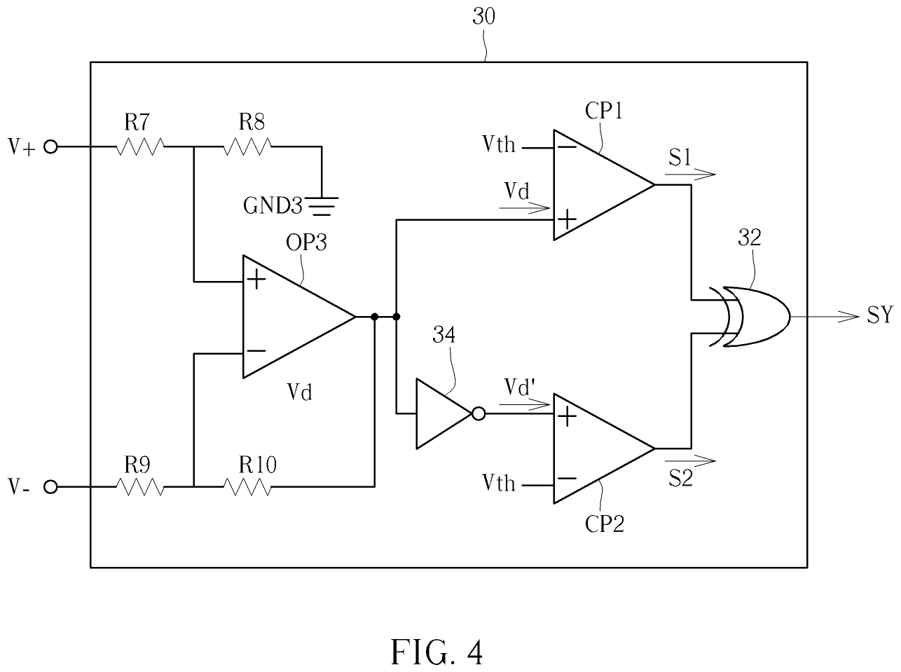

FIG. 4 is a diagram illustrating an implementation of the comparator module 30 in the amplifier DC bias protection circuit 100 according to an embodiment of the present invention. The comparator module 30 includes an operational amplifier OP3, comparators CP1-CP2, a judging circuit 32, an inverter 34 and resistors R7-R10. The operational amplifier OP3 includes a non-inverting input end coupled to the filter module 20 via the resistor R7 for receiving the DC bias signal V+, an inverting input end coupled to the filter module 20 via the resistor R9 for receiving the DC bias signal V−, and an output end coupled to the non-inverting input end of the operational amplifier OP3 via the resistor R10, wherein the resistor R8 is coupled between the non-inverting input end of the operational amplifier OP3 and a ground voltage GND3. The operational amplifier OP3 is configured to provide a DC bias difference signal Vd at its output end according to the values of the DC bias signals V+ and V−. The relationship between the DC bias signal V+, the DC bias signal V− and the DC bias difference signal Vd may be represented by the following equation (1):

Vd=V+*[(R8/(R7+R8))*[(R9+R10)/R9)]−V−*(R10/R9) . . . (1)

Assuming that R7=R9 and R8=R10, equation (1) can be simplified to Vd=(R8/R7)*(V+−V−), which means the gain G3 of the operational amplifier OP3 is equal to (R8/R7). In an embodiment of the present invention, the values of the resistors R7-R10 are determined in a way so that G3<1, thereby limiting the value of DC bias difference signal Vd.

The comparator CP1 is configured to provide a comparison signal S1 according to the relationship between the DC bias difference signal Vd and a threshold voltage Vth. The comparator CP1 includes a non-inverting input end coupled to the output end of the operational amplifier OP3 for receiving the DC bias difference signal Vd, an inverting input end coupled to the threshold voltage Vth, and an output end for outputting the comparison signal S1. The comparator CP2 is configured to provide a comparison signal S2 according to the relationship between an inverting DC bias difference signal Vd′ and the threshold voltage Vth. The comparator CP2 includes a non-inverting input end coupled to the output end of the operational amplifier OP3 via the inverter 34 for receiving the inverting DC bias difference signal Vd′, an inverting input end coupled to the threshold voltage Vth, and an output end for outputting the comparison signal S2, wherein Vd′=−Vd.

For illustrative purpose, it is assumed that the threshold voltage Vth has a positive value. When the DC bias difference signal Vd has a positive value greater than the positive threshold voltage Vth, the inverting DC bias difference signal Vd′ has a negative value which cannot be greater than the positive threshold voltage Vth. Under such circumstance, the comparator CP1 is configured to output the comparison signal S1 having a first level (such as logic 1), and the comparator CP2 is configured to output the comparison signal S2 having a second level (such as logic 0). When the DC bias difference signal Vd has a negative value and the corresponding inverting DC bias difference signal Vd′ has a positive value greater than the positive threshold voltage Vth, the negative DC bias difference signal Vd cannot be greater than the positive threshold voltage Vth. Under such circumstance, the comparator CP1 is configured to output the comparison signal S1 having the second level (such as logic 0), and the comparator CP2 is configured to output the comparison signal S2 having the first level (such as logic 1). When the absolute value of the DC bias difference signal Vd is between 0 and the threshold voltage Vth, it is impossible for the condition Vd>Vth or Vd′>Vth to be satisfied. Under such circumstance, the comparator CP1 is configured to output the comparison signal S1 having the second level (such as logic 0), and the comparator CP2 is configured to output the comparison signal S2 having the second level (such as logic 0).

In an embodiment of the present invention, the judge circuit 32 maybe an exclusive-OR gate configured to output the determination SY according to the comparison signals S1 and S2. The judge circuit 32 includes a first input end coupled to the output end of the comparator CP1 for receiving the comparison signal S1, a second input end coupled to the output end of the comparator CP2 for receiving the comparison signal S2, and an output end for outputting the determination signal SY. As well-known to those skilled in the art, the judge circuit 32 implemented as an exclusive-OR gate is configured to output a logic 0 determination SY when its first input end and its second input end have different logic levels, and output a logic 1 determination SY when its first input end and its second input end have the same logic level. It is to be noted that the circuit structure depicted in FIG. 4 is merely an embodiment of the present comparator module 30, but does not limit the scope of the present invention.

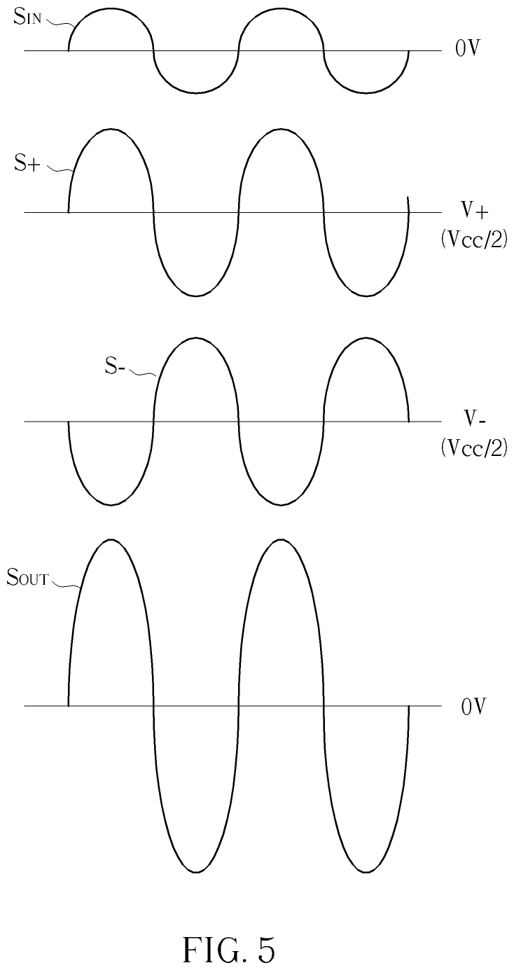

FIG. 5 is a diagram illustrating related signals during the operation of the amplifier DC bias protection circuit 100 in an ideal condition according to an embodiment of the present invention. For illustrative purpose, it is assumed that the input signal S_{IN} is a sinusoidal wave with zero DC bias, that the operational amplifier OP1 in the amplifier module 10 provides the non-inverting signal S+as a sinusoidal wave with a DC bias equal to V+ (V+ is not equal to zero), and that the operational amplifier OP2 in the amplifier module 10 provides the inverting signal S− as a sinusoidal wave with a DC bias equal to V− (V− is not equal to zero). In the ideal condition, the non-inverting signal S+ and the inverting signal S1 have the same DC bias (V+ is equal to V−) so that the DC bias V+ and the DC bias V− can cancel each other at the speaker module 40 for outputting the speaker output signal Sour having zero DC bias.

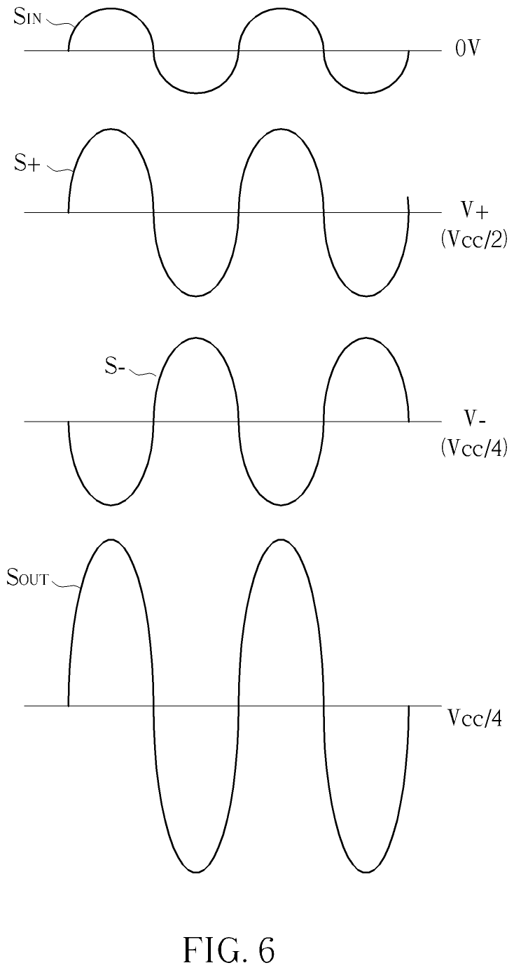

FIG. 6 is a diagram illustrating related signals during the operation of the amplifier DC bias protection circuit 100 in a non-ideal condition according to an embodiment of the present invention. Due to variations in device characteristics or other factors, the actual gains of the operational amplifier OP1 and OP2 may be different under the design G1=−G2, thereby resulting in a non-zero DC bias difference signal Vd between the non-inverting signal S+ and the inverting signal S−. If the DC bias V+ of the non-inverting signal S+ is equal to Vcc/2 but the DC bias V− of the inverting signal S− is equal to Vcc/4, the speaker output signal Sour outputted by the speaker module 40 has a non-zero DC bias (Vd=Vcc/4) after cancellation.

As previous depicted, when the comparator module 30 determines that the absolute value of the DC bias difference signal Vd is greater than the threshold voltage (Vd>Vth or Vd′>Vth), it indicates that the difference between the DC bias V+ of the non-inverting signal S+ and the DC bias V− of the inverting signal S− is too large, and the large DC bias of the resulting speaker output signal SouT may cause circuit damages. Under such circumstance, the judging circuit 32 is configured to output the determination signal SY having the first level (such as logic 1) for deactivating the amplifier module 10. When the comparator module determines that the absolute value of the DC bias difference signal Vd is not greater than the threshold voltage, it indicates that the difference between the DC bias V+ of the non-inverting signal S+ and the DC bias V− of the inverting signal S− is essentially zero. Under such circumstance, the judging circuit 32 is configured to output the determination signal SY having the second level (such as logic 0) so that the amplifier module 10 may continue to operate normally.

In conclusion, in the amplifier DC bias protection circuit of the present invention, the amplifier module is configured to convert the input signal into the non-inverting signal and the inverting signal for driving the speaker module. The filter module is configured to provide two DC bias signals associated with the DC biases of the non-inverting signal and the inverting signal. The comparator module is configured to provide the DC bias difference signal is associated with the voltage difference between the first DC bias signal and the second DC bias signal and output the determination signal for deactivating the amplifier module when the absolute value of the DC bias difference signal is greater than the predetermined value in order to prevent the speaker output signal with large DC bias from causing circuit damages.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplifier direct-current (DC) bias protection circuit, comprising:
an amplifier module configured to convert an input signal into a non-inverting signal and an inverting signal;
a filter module configured to:
block an alternative-current (AC) component in the non-inverting signal for providing a corresponding first DC bias signal; and
block an AC component in the inverting signal for providing a corresponding second DC bias signal; and
a comparator module configured to:
determine whether an absolute value of a DC bias difference signal is greater than a predetermined value; and
output a determination signal for deactivating the amplifier module when the absolute value of the DC bias difference signal is greater than the predetermined value, wherein the DC bias difference signal is associated with a voltage difference between the first DC bias signal and the second DC bias signal.

2. The amplifier DC bias protection circuit of claim 1, wherein the amplifier module comprises:
a first operational amplifier module configured to provide the non-inverting signal by amplifying the input signal with a first gain having a positive value; and
a second operational amplifier module configured to provide the inverting signal by amplifying the input signal with a second gain having a negative value.

3. The amplifier DC bias protection circuit of claim 2, wherein:
the amplifier module further comprises a first resistor, a second resistor, a third resistor, and a fourth resistor;
the first operational amplifier comprises:
a non-inverting input end coupled to the input signal;
an inverting input end coupled to a ground voltage via the first resistor; and
an output end coupled to the inverting input end of the first operational amplifier via the second resistor for outputting the non-inverting signal; and
the second operational amplifier comprises:
a non-inverting input end coupled to the ground voltage;
an inverting input end coupled to the input signal via the third resistor; and
an output end coupled to the inverting input end of the second operational amplifier via the fourth resistor for outputting the inverting signal.

4. The amplifier DC bias protection circuit of claim 1, wherein the filter module comprises:
a fifth resistor, including:
a first end coupled to the amplifier module for receiving the non-inverting signal; and
a second end for outputting the first DC bias signal;
a sixth resistor, including:
a first end coupled to the amplifier module for receiving the inverting signal; and
a second end for outputting the second DC bias signal;
a first capacitor coupled between the second end of the fifth resistor and a ground voltage; and
a second capacitor coupled between the second end of the sixth resistor and the ground voltage.

5. The amplifier DC bias protection circuit of claim 1, wherein the comparator module comprises a third operational amplifier module configured to provide the DC bias difference signal by amplifying the voltage difference between the first DC bias signal and the second DC bias signal with a third gain.

6. The amplifier DC bias protection circuit of claim 5, wherein:
the comparator module further comprises a seventh resistor, an eighth resistor, a ninth resistor, and a tenth resistor;
the third operational amplifier comprises:
a non-inverting input end coupled to the first DC bias signal via the seventh resistor;
an inverting input end coupled to the second DC bias signal via the ninth resistor; and
an output end coupled to the inverting input end of the third operational amplifier via the tenth resistor for outputting the DC bias difference signal.

7. The amplifier DC bias protection circuit of claim 6, wherein the comparator module further comprises:
a first comparator configured to provide a first comparison signal according to a relationship between the DC bias difference signal and a threshold voltage, and comprising:
a non-inverting input end coupled to the output end of the third operational amplifier for receiving the DC bias difference signal;
an inverting input end coupled to the threshold voltage; and
an output end for outputting the first comparison signal; and
a second comparator configured to provide a second comparison signal according to a relationship between an inverting DC bias difference signal and the threshold voltage, and comprising:
a non-inverting input end coupled to the inverting DC bias difference signal which is an inverting signal of the DC bias difference signal;
an inverting input end coupled to the threshold voltage; and
an output end for outputting the second comparison signal.

8. The amplifier DC bias protection circuit of claim 7, wherein the comparator module further comprises an inverter configured to convert the DC bias difference signal into the inverting DC bias difference signal.

9. The amplifier DC bias protection circuit of claim 7, wherein the comparator module further comprises an judging circuit configured to output the determination signal according to a voltage level of the first comparison signal and a voltage level of the second comparison signal.

10. The amplifier DC bias protection circuit of claim 9, wherein the judging circuit is an exclusive-OR gate which includes:
a first input end coupled to the output end of the first comparator for receiving the first comparison signal;
a second input end coupled to the output end of the second comparator for receiving the second comparison signal; and
an output end for outputting the determination signal.

11. An audio system which provides signal amplification and direct-current (DC) bias protection, comprising:
a speaker module; and
an amplifier DC bias protection circuit, comprising:
an amplifier module configured to convert an input signal into a non-inverting signal and an inverting signal for driving the speaker module;
a filter module configured to:
block an alternative-current (AC) component in the non-inverting signal for providing a corresponding first DC bias signal; and
block an AC component in the inverting signal for providing a corresponding second DC bias signal; and
a comparator module configured to:
determine whether an absolute value of a DC bias difference signal is greater than a predetermined value; and
output a determination signal for deactivating the amplifier module when the absolute value of the DC bias difference signal is greater than the predetermined value, wherein the DC bias difference signal is associated with a voltage difference between the first DC bias signal and the second DC bias signal.

12. The audio system of claim 11, wherein the amplifier module comprises:
a first operational amplifier module configured to provide the non-inverting signal by amplifying the input signal with a first gain having a positive value; and
a second operational amplifier module configured to provide the inverting signal by amplifying the input signal with a second gain having a negative value.

13. The audio system of claim 12, wherein:
the amplifier module further comprises a first resistor, a second resistor, a third resistor, and a fourth resistor;
the first operational amplifier comprises:
a non-inverting input end coupled to the input signal;
an inverting input end coupled to a ground voltage via the first resistor; and
an output end coupled to the inverting input end of the first operational amplifier via the second resistor for outputting the non-inverting signal; and
the second operational amplifier comprises:
a non-inverting input end coupled to the ground voltage;
an inverting input end coupled to the input signal via the third resistor; and
an output end coupled to the inverting input end of the second operational amplifier via the fourth resistor for outputting the inverting signal.

14. The audio system of claim 11, wherein the filter module comprises:
a fifth resistor, including:
a first end coupled to the amplifier module for receiving the non-inverting signal; and
a second end for outputting the first DC bias signal;
a sixth resistor, including:
a first end coupled to the amplifier module for receiving the inverting signal; and
a second end for outputting the second DC bias signal;
a first capacitor coupled between the second end of the fifth resistor and a ground voltage; and
a second capacitor coupled between the second end of the sixth resistor and the ground voltage.

15. The audio system of claim 11, wherein the comparator module comprises a third operational amplifier module configured to provide the DC bias difference signal by amplifying the voltage difference between the first DC bias signal and the second DC bias signal with a third gain.

16. The audio system of claim 15, wherein:
the comparator module further comprises a seventh resistor, an eighth resistor, a ninth resistor, and a tenth resistor;
the third operational amplifier comprises:
a non-inverting input end coupled to the first DC bias signal via the seventh resistor;
an inverting input end coupled to the second DC bias signal via the ninth resistor; and
an output end coupled to the inverting input end of the third operational amplifier via the tenth resistor for outputting the DC bias difference signal.

17. The audio system of claim 16, wherein the comparator module further comprises:
a first comparator configured to provide a first comparison signal according to a relationship between the DC bias difference signal and a threshold voltage, and comprising:
a non-inverting input end coupled to the output end of the third operational amplifier for receiving the DC bias difference signal;
an inverting input end coupled to the threshold voltage; and
an output end for outputting the first comparison signal; and
a second comparator configured to provide a second comparison signal according to a relationship between an inverting DC bias difference signal and the threshold voltage, and comprising:
a non-inverting input end coupled to the inverting DC bias difference signal which is an inverting signal of the DC bias difference signal;
an inverting input end coupled to the threshold voltage; and
an output end for outputting the second comparison signal.

18. The audio system of claim 17, wherein the comparator module further comprises an inverter configured to convert the DC bias difference signal into the inverting DC bias difference signal.

19. The audio system of claim 17, wherein the comparator module further comprises an judging circuit configured to output the determination signal according to a voltage level of the first comparison signal and a voltage level of the second comparison signal.

20. The audio system of claim 19, wherein the judging circuit is an exclusive-OR gate which includes:
a first input end coupled to the output end of the first comparator for receiving the first comparison signal;
a second input end coupled to the output end of the second comparator for receiving the second comparison signal; and
an output end for outputting the determination signal.
